(19) United States
(12) Patent Application Publication
(10) Pub. No.: US 2024/0333240 A1
(43) Pub. Date: Oct. 3, 2024

(54) ERROR AMPLIFIER AND POWER SUPPLY

(71) Applicant: HANGZHOU BRIGHT POWER SEMICONDUCTOR CO., LTD., Hangzhou (CN)

(72) Inventors: Xiaohua SU, Hangzhou (CN); Zhihui QI, Hangzhou (CN)

(21) Appl. No.: 18/590,483

(22) Filed: Feb. 28, 2024

(30) Foreign Application Priority Data
Mar. 31, 2023 (CN) 202310365359.8

(51) Int. Cl. H03F 3/45; H02M 1/08

(52) U.S. Cl. CPC H03F 3/45475; H02M 1/08

(57) ABSTRACT

The present invention provides an error amplifier and a power supply. In the error amplifier, a pre-amplifier takes an amplification action in response to a fluctuation in a feedback voltage, allowing more accurate selective activation of a pull-up circuit, a pull-down circuit or a steady-state circuit. This can reduce accuracy requirements for OTAs therein and hence design requirements for the error amplifier. Moreover, in the event of a loading transition, the pull-up or pull-down circuit can be selectively activated to sooner pull up or down a voltage at an output terminal of the error amplifier. This effectively improves load transient response performance of the loop while not affecting its loop stability.

### CROSS-REFERENCES TO RELATED APPLICATION

This application claims the priority of Chinese patent application number 202310365359.8, filed on Mar. 31, 2023, the entire contents of which are incorporated herein by reference.

### TECHNICAL FIELD

The present invention relates to the field of electrical and electronic technology and, in particular, to an error amplifier and a power supply.

### BACKGROUND

As a core circuit of a switched-mode power supply (SMPS) or linear power supply, an error amplifier usually includes a linear or non-linear operational transconductance amplifier (OTA) with an output terminal typically connected to a compensation network. The OTA and the compensation network can be used to adjust stability, load regulation, load transient response and other performance metrics of a feedback loop of the circuit. However, since the stability and load transient response of the feedback loop are mutually restrictive, a tradeoff must be made between the two metrics during the practical design of a particular error amplifier.

### SUMMARY

It is an objective of the present invention to provide an error amplifier, which overcomes the problem that existing error amplifiers could not satisfy both loop stability and load transient response.

To this end, the present invention provides an error amplifier including: a steady-state circuit including a pre-amplifier and a first OTA, a first input terminal of the pre-amplifier configured to receive a reference voltage, a second input terminal of the pre-amplifier configured to receive a feedback voltage, first and second input terminals of the first OTA coupled to first and second output terminals of the pre-amplifier, respectively, an output terminal of the first OTA connected to an output terminal of the error amplifier; a pull-up circuit, a first input terminal of the pull-up circuit coupled to the first output terminal of the pre-amplifier, a second input terminal of the pull-up circuit coupled to the second output terminal of the pre-amplifier, the pull-up circuit configured to perform a pull-up operation when a difference between voltages at the first and second output terminals of the pre-amplifier is higher than a first predetermined voltage; and a pull-down circuit, a first input terminal of the pull-down circuit coupled to the first output terminal of the pre-amplifier, a second input terminal of the pull-down circuit coupled to the second output terminal of the pre-amplifier, the pull-down circuit configured to perform a pull-down operation when a difference between the voltages at the second and first output terminals of the pre-amplifier is higher than a second predetermined voltage.

Optionally, the pull-up circuit may include a second OTA and a pull-up unit connected between an output terminal of the second OTA and the output terminal of the first OTA, first and second input terminals of the second OTA coupled to the first and second output terminals of the pre-amplifier, respectively, wherein the pull-down circuit includes a third OTA and a pull-down unit coupled between an output terminal of the third OTA and the output terminal of the first OTA, first and second input terminals of the third OTA coupled to the first and second output terminals of the pre-amplifier, respectively.

Optionally, the pull-up circuit includes a first bias voltage source for providing the first predetermined voltage, the first bias voltage source coupled between the first input terminal of the second OTA and the first output terminal of the pre-amplifier, or between the second input terminal of the second OTA and the second output terminal of the pre-amplifier. Additionally or alternatively, the pull-down circuit includes a second bias voltage source for providing the second predetermined voltage, the second bias voltage source coupled between the second input terminal of the third OTA and the second output terminal of the pre-amplifier, or between the first input terminal of the third OTA and the first output terminal of the pre-amplifier.

Optionally, the pull-up circuit includes a first bias current source for providing a first bias current which is configured according to the product of the first predetermined voltage and a transconductance gain of the second OTA, a first terminal of the first bias current source coupled to the output terminal of the second OTA, a second terminal of the first bias current source grounded. Additionally or alternatively, the pull-down circuit includes a second bias current source for providing a second bias current which is configured according to the product of the second predetermined voltage and a transconductance gain of the third OTA, a first terminal of the second bias current source coupled to the output terminal of the third OTA, a second terminal of the second bias current source coupled to a power supply voltage.

Optionally, the pull-up circuit may include at least two second OTAs, first and second input terminals of each second OTA coupled to the first and second output terminals of the pre-amplifier, respectively, with a respective pull-up unit being connected between an output terminal of each second OTA and the output terminal of the first OTA. Additionally or alternatively, the pull-down circuit may include at least two third OTAs, first and second input terminals of each third OTA coupled to the first and second output terminals of the pre-amplifier, respectively, with a respective pull-down unit being connected between an output terminal of each third OTA and the output terminal of the first OTA.

Optionally, a first bias voltage source may be coupled between the first input terminal of each second OTA and the first output terminal of the pre-amplifier, or between the second input terminal of each second OTA and the second output terminal of the pre-amplifier. Additionally or alternatively, a second bias voltage source may be coupled between the second input terminal of each third OTA and the second output terminal of the pre-amplifier, or between the first input terminal of each third OTA and the first output terminal of the pre-amplifier.

Optionally, a first bias current source may be coupled to an output terminal of each second OTA. Additionally or alternatively, a second bias current source may be coupled to an output terminal of each third OTA.

Optionally, the pull-up unit may include a first transistor, a second transistor, a third transistor and a fourth transistor. A control terminal and a first terminal of the first transistor and a control terminal of the second transistor may be coupled to one another and then together to the output terminal of the first OTA. A second terminal of the first transistor and a second terminal of the second transistor may be coupled to each other and then both grounded. A first terminal of the second transistor may be coupled to a first terminal of the third transistor. A first terminal and a control terminal of the third transistor and a control terminal of the fourth transistor may be coupled to one another. A second terminal of the third transistor and a second terminal of the fourth transistor may be coupled to each other and then both to a power supply voltage. A first terminal of the fourth transistor may be connected to the output terminal of the first OTA.

Optionally, the pull-down unit may include a fifth transistor, a sixth transistor, a seventh transistor and an eighth transistor. A control terminal and a first terminal of the fifth transistor and a control terminal of the sixth transistor may be coupled to one another and then together to the output terminal of the third OTA. A second terminal of the fifth transistor and a second terminal of the sixth transistor may be coupled to each other and then both to a power supply voltage. A first terminal of the sixth transistor, a first terminal and a control terminal of the seventh transistor and a control terminal of the eighth transistor may be coupled to one another. A second terminal of the seventh transistor and a second terminal of the eighth transistor may be coupled to each other and then both grounded. A first terminal of the eighth transistor may be connected to the output terminal of the first OTA.

Optionally, the pull-up unit may include a first switch coupled between the output terminal of the second OTA and the output terminal of the first OTA. Additionally or alternatively, the pull-down unit may include a second switch coupled between the output terminal of the third OTA and the output terminal of the first OTA.

The present invention also provides a power supply including the error amplifier as defined above. The power supply may be, for example, a current-mode power supply, in which the error amplifier generates an amplified error signal for controlling a peak value of a current through an inductor in the power supply. Alternatively, the power supply may be, for example, a voltage-mode power supply, in which the error amplifier generates an amplified error signal for controlling a duty cycle of a power transistor in the power supply.

In the error amplifier of the present invention, receiving the reference voltage and the feedback voltage and amplifying the difference therebetween by the pre-amplifier enables more accurate selective activation of the pull-up circuit, the pull-down circuit and the steady-state circuit in the event of fluctuations in the feedback voltage. In this way, less stringent requirements can be placed on accuracy, for example, input offset voltage accuracy of the OTAs in the error amplifier of the present invention (including the first, second and third OTAs), reducing requirements on the design of the error amplifier.

Additionally, in the event of a loading transition, the pull-up or pull-down circuit can be selectively activated to allow the voltage from the output terminal of the error amplifier to be sooner pulled up or down, thereby reducing maximum overshoot during the loading transition and effectively improving load transient response performance of the loop. In particular, a significant reduction in maximum overshoot on load transient response can be achieved in the event of a large loading transition. Thus, according to the present invention, in response to a particular loading condition, one of the circuits can be selectively activated, thereby improving the loop's load transient response without affecting its stability.

### BRIEF DESCRIPTION OF THE DRAWINGS

FIG. 1 is a schematic circuit diagram of an error amplifier according to a first embodiment of the present invention.

FIG. 2 is a schematic circuit diagram of a pull-up circuit in the error amplifier according to the first embodiment of the present invention.

FIG. 3 is a schematic circuit diagram of a pull-down circuit in the error amplifier according to the first embodiment of the present invention.

FIG. 4 is a schematic circuit diagram of a pull-up circuit in an error amplifier according to a second embodiment of the present invention.

FIG. 5 is a schematic circuit diagram of a pull-down circuit in an error amplifier according to the second embodiment of the present invention.

FIG. 6 is a schematic circuit diagram of an error amplifier according to a third embodiment of the present invention.

### DETAILED DESCRIPTION

The error amplifier and power supply proposed herein will be described in greater detail below with reference to specific embodiments and to the accompanying drawings. From the following description, advantages and features of the present invention will become more apparent. Note that the figures are provided in a very simplified form not necessarily drawn to exact scale and for the only purpose of facilitating easy and clear description of the embodiments.

### Embodiment 1

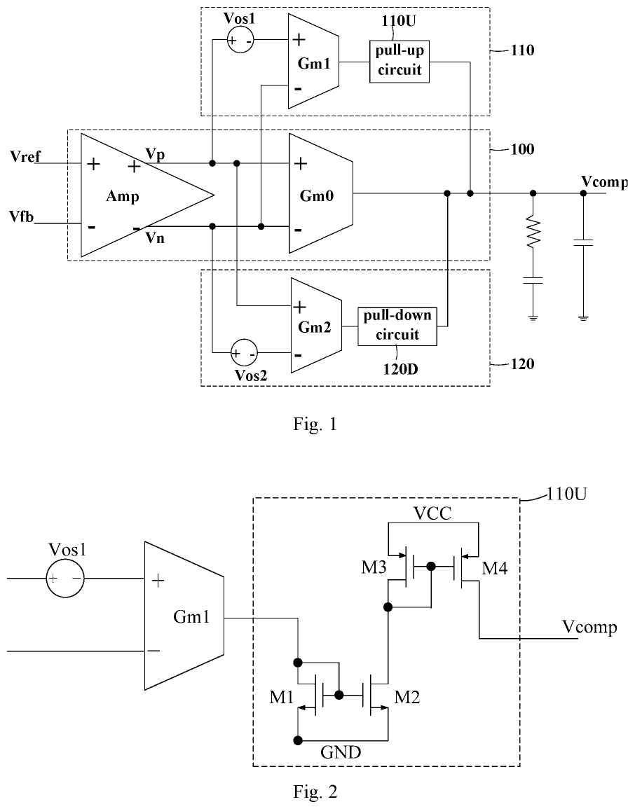

FIG. 1 is a schematic circuit diagram of an error amplifier according to a first embodiment of the present invention. As shown in FIG. 1, the error amplifier includes a steady-state circuit 100, a pull-up circuit 110 and a pull-down circuit 120.

Specifically, the steady-state circuit 100 includes a pre-amplifier Amp and a first operational transconductance amplifier (OTA) Gm0. The first input terminal of the pre-amplifier Amp is configured to receive a reference voltage Vref and the second input terminal of the pre-amplifier Amp is configured to receive a feedback voltage Vfb. First and second input terminals of the first OTA Gm0 are coupled to first and second output terminals of the pre-amplifier Amp, respectively. An output terminal of the first OTA Gm0 is connected to an output terminal of the error amplifier. The first OTA Gm0 may be either linear, or non-linear. Input terminals of the pull-up circuit 110 and the pull-down circuit 120 are connected in parallel to the output terminals of the pre-amplifier Amp. The feedback voltage Vfb may be, for example, a feedback output from an output terminal of a power supply, which can directly or indirectly reflect a specific loading condition at the circuit's output terminal.

Specifically, the pull-up circuit 110 includes a second OTA Gm1 and a pull-up unit 110U connected between an output terminal of the second OTA Gm1 and the output terminal of the first OTA Gm0. The pull-down circuit 120 includes a third OTA Gm2 and a pull-down unit 120D connected between an output terminal of the third OTA Gm2 and the output terminal of the first OTA Gm0. First input terminals of the second OTA Gm1 and the third OTA Gm2 are both coupled to the first output terminal of the pre-amplifier Amp, and second input terminals of the second OTA Gm1 and the third OTA Gm2 are both coupled to the second output terminal of the pre-amplifier Amp. An input terminal of the pull-up unit 110U is coupled to the output terminal of the second OTA Gm1, and an input terminal of the pull-down unit 120D is coupled to the output terminal of the third OTA Gm2. Output terminals of the pull-up unit 110U and the pull-down unit 120D are both coupled to the output terminal of the first OTA Gm0. The second OTA Gm1 and the third OTA Gm2 may be either linear, or non-linear.

When a difference between a voltage Vp at the first output terminal of the pre-amplifier Amp and a voltage Vn at the second output terminal of the pre-amplifier Amp, i.e., (Vp−Vn), is higher than a first predetermined voltage V1, the pull-up circuit 110 is activated to perform a pull-up operation to pull up an output signal Vcomp from the output terminal of the error amplifier. When a difference between the voltage Vn at the second output terminal of the pre-amplifier Amp and the voltage Vp at the first output terminal thereof, i.e., (Vn−Vp), is higher than a second predetermined voltage V2, the pull-down circuit 120 is activated to perform a pull-down operation to pull down the output signal Vcomp from the output terminal of the error amplifier. When the difference (Vp−Vn) of the voltage Vp at the first output terminal of the pre-amplifier Amp and the voltage Vn at the second output terminal thereof is lower than the first predetermined voltage V1 and the difference (Vn−Vp) of the voltage Vn at the second output terminal and the voltage Vp at the first output terminal is lower than the second predetermined voltage V2, i.e., −V2<Vp−Vn<V1, the steady-state circuit 100 is activated, and the output signal Vcomp is output directly.

In practical use, in response to a loading transition, for example, from light to heavy loading, or from heavy to light or zero loading, the feedback voltage Vfb received by the pre-amplifier Amp will experience a change, leading to a large value of the voltage difference (Vp−Vn) between the voltage Vp at the first output terminal of the pre-amplifier Amp and the voltage Vn at the second output terminal thereof. When the voltage difference (Vp−Vn) exceeds the range [−V2, V1], the pull-up circuit 110 or the pull-down circuit 120 is activated to pull the output signal Vcomp up or down to a desired value sooner than as is typical, reducing maximum overshoot during loading transitions.

In this embodiment, receiving the reference voltage Vref and the feedback voltage Vfb and amplifying the difference therebetween by the pre-amplifier Amp enables more accurate selective activation of the pull-up circuit 110, the pull-down circuit 120 and the steady-state circuit 100 in the event of fluctuations in the feedback voltage Vfb. In this way, less stringent requirements can be placed on accuracy, in particular input offset voltage accuracy of the second OTA Gm1 in the pull-up circuit 110, the third OTA Gm2 in the pull-down circuit 120 and the first OTA Gm0 in the steady-state circuit 100, reducing requirements on the design of the error amplifier.

Further, in the event of a loading transition, the pull-up circuit 110 or the pull-down circuit 120 can be selectively activated to allow the output signal Vcomp from the output terminal of the error amplifier to be sooner pulled up or down, leading to an improvement in load transient response performance of the loop. In particular, maximum overshoot of the output signal Vcomp during a loading transition can be significantly reduced. That is, in this embodiment, for a particular loading condition, one of the circuits can be selectively activated, thereby improving the loop's load transient response without affecting its stability.

With continued reference to FIG. 1, the pull-up circuit 110 comprises a bias power supply for providing the first predetermined voltage V1 or a first bias current. In the embodiment shown in FIG. 1, the bias power supply is implemented as a first bias voltage source Vos1, which is coupled between the first input terminal of the second OTA Gm1 and the first output terminal of the pre-amplifier Amp and configured to provide the first predetermined voltage V1. A positive terminal of the first bias voltage source Vos1 is connected to the first output terminal of the pre-amplifier Amp, and a negative terminal of the first bias voltage source Vos1 is connected to the first input terminal of the second OTA Gm1. When the difference (Vp−Vn) between the voltage Vp at the first output terminal of the pre-amplifier Amp and the voltage Vn at the second output terminal thereof is greater than the first predetermined voltage V1, a current output through the second OTA Gm1 can activate the pull-up unit 110U to allow it to perform a pull-up operation. In an alternative embodiment, the first bias voltage source Vos1 is coupled between the second input terminal of the second OTA Gm1 and the second output terminal of the pre-amplifier Amp and is configured to provide the first predetermined voltage V1. In this case, the negative terminal of the first bias voltage source Vos1 is connected to the second output terminal of the pre-amplifier Amp, and the positive terminal of the first bias voltage source Vos1 is connected to the second input terminal of the second OTA Gm1.

Likewise, the pull-down circuit 120 comprises a bias power supply for providing the second predetermined voltage V2 or a second bias current. In the embodiment shown in FIG. 1, the bias power supply is implemented as a second bias voltage source Vos2, which is coupled between the second input terminal of the third OTA Gm2 and the second output terminal of the pre-amplifier Amp and is configured to provide the second predetermined voltage V2. A positive terminal of the second bias voltage source Vos2 is connected to the second output terminal of the pre-amplifier Amp, and a negative terminal of the second bias voltage source Vos2 is connected to the second input terminal of the third OTA Gm2. When the difference (Vn−Vp) between the voltage Vn at the second output terminal of the pre-amplifier Amp and the voltage Vp at the first output terminal thereof is greater than the second predetermined voltage V2, a current output through the third OTA Gm2 can activate the pull-down unit 120D to allow it to perform a pull-down operation. In an alternative embodiment, the second bias voltage source Vos2 is coupled between the first input terminal of the third OTA Gm2 and the first output terminal of the pre-amplifier Amp and is configured to provide the second predetermined voltage V2. The negative terminal of the second bias voltage source Vos2 is connected to the first output terminal of the pre-amplifier Amp, and the positive terminal of the second bias voltage source Vos2 is connected to the first input terminal of the third OTA Gm2.

In one embodiment, referring to FIG. 1, the pull-up unit 110U may include a first switch coupled between the output terminals of the second and first OTAs. The first switch may be a diode with an anode coupled to the output terminal of the second OTA Gm1 and a cathode coupled to the output terminal of the first OTA Gm0. The pull-down unit 120D may include a second switch coupled between the output terminals of the third and the first OTAs. The second switch may be a diode with a cathode coupled to the output terminal of the third OTA Gm2 and an anode coupled to the output terminal of the first OTA Gm0.

In one embodiment, referring to FIG. 2, the pull-up unit 110U may include a first transistor M1, a second transistor M2, a third transistor M3 and a fourth transistor M4. A control terminal and a first terminal of the first transistor M1 and a control terminal of the second transistor M2 are coupled to one another and then together to the output terminal of the second OTA Gm1. A second terminal of the first transistor M1 and a second terminal of the second transistor M2 are coupled to each other and then both grounded GND. A first terminal of the second transistor M2 is coupled to a first terminal of the third transistor M3. A first terminal and a control terminal of the third transistor M3 and a control terminal of the fourth transistor M4 are coupled to one another. A second terminal of the third transistor M3 and a second terminal of the fourth transistor M4 are coupled to each other and then both to a power supply voltage VCC. A first terminal of the fourth transistor M4 is connected to the output terminal of the error amplifier. The first transistor M1 and the second transistor M2 are, for example, NMOS transistors, and the third transistor M3 and the fourth transistor M4 are, for example, PMOS transistors.

In practice, the pull-up unit 110U receives a current output from the second OTA Gm1, which pulls up the output signal Vcomp through the first transistor M1, the second transistor M2, the third transistor M3 and the fourth transistor M4.

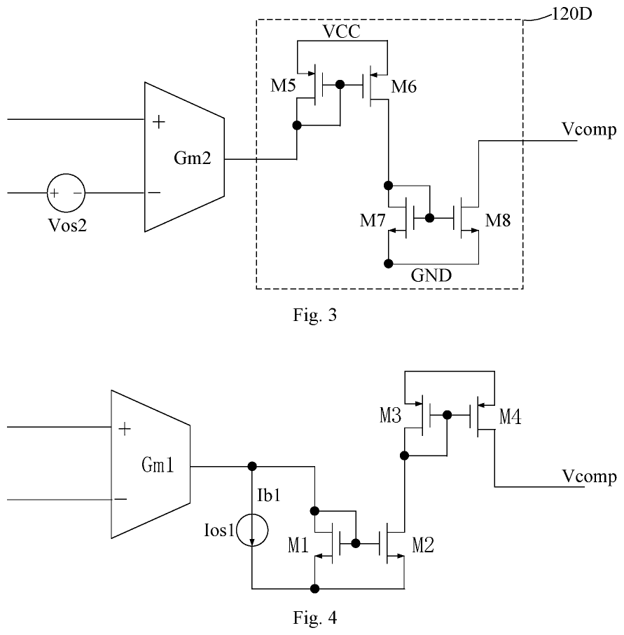

In one embodiment, referring to FIG. 3, the pull-down unit 120D may include a fifth transistor M5, a sixth transistor M6, a seventh transistor M7 and an eighth transistor M8. A control terminal and a first terminal of the fifth transistor M5 and a control terminal of the sixth transistor M6 may be coupled to one another and then together to the output terminal of the third OTA Gm2. A second terminal of the fifth transistor M5 and a second terminal of the sixth transistor M6 are coupled to each other and then both to the power supply voltage VCC. A first terminal of the sixth transistor M6, a first terminal and a control terminal of the seventh transistor M7 and a control terminal of the eighth transistor M8 are coupled to one another. A second terminal of the seventh transistor M7 and a second terminal of the eighth transistor M8 are coupled to each other and then both grounded GND. A first terminal of the eighth transistor M8 is connected to the output terminal of the error amplifier. The fifth transistor M5 and the sixth transistor M6 are, for example, PMOS transistors, and the seventh transistor M7 and the eighth transistor M8 are, for example, NMOS transistors.

In practice, the pull-down unit 120D receives a current output from the third OTA Gm2, which pulls down the output signal Vcomp through the fifth transistor M5, the sixth transistor M6, the seventh transistor M7 and the eighth transistor M8.

### Embodiment 2

In the first embodiment, the bias power supplies in the pull-up and pull-down circuits are implemented as bias voltage sources. Differing from the first embodiment, in a second embodiment, the bias power supplies in the pull-up and pull-down circuits are implemented as bias current sources, which are connected to the output terminals of the OTAs.

Specifically, referring to FIG. 4, a first bias current source Ios1 may be provided in the pull-up circuit. A first terminal of the first bias current source Ios1 is coupled to the output terminal of the second OTA Gm1, and a second terminal of the first bias current source Ios1 is grounded GND. When the difference AV between the voltage Vp at the first output terminal of the pre-amplifier Amp and the voltage Vn at the second output terminal thereof is greater than the first predetermined voltage V1, the pull-up unit 110U can be activated by a current output through the second OTA Gm1 superimposed with a current provided by the first bias current source Ios1 to carry out a pull-up operation.

It is to be noted that the first bias current Ib1 provided by the first bias current source Ios1 in this embodiment is configured according to the product of the first predetermined voltage V1 and a transconductance gain gm1 of the second OTA Gm1. Specifically, the first bias current Ib1 provided by the first bias current source Ios1 in this embodiment and the first predetermined voltage V1 provided by the first bias voltage source Vos1 in the first embodiment may satisfy the following relationship: V1=Ib1/gm1.

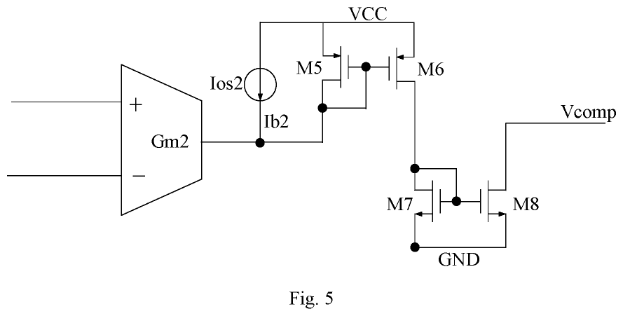

Referring to FIG. 5, a second bias current source Ios2 may be provided in the pull-down circuit. A first terminal of the second bias current source Ios2 is coupled to the output terminal of the third OTA Gm2, and a second terminal of the second bias current source Ios2 is coupled to the power supply voltage VCC. When the difference AV between the voltage Vp at the first output terminal of the pre-amplifier Amp and the voltage Vn at the second output terminal thereof is <−V2, the pull-down unit can be activated by a current output from the third OTA Gm2 superimposed with a second bias current Ib2 provided by the second bias current source Ios2 to carry out a pull-down operation.

It is to be noted that the second bias current Ib2 provided by the second bias current source Ios2 in this embodiment is configured according to the product of the second predetermined voltage V2 and a transconductance gain gm2 of the third OTA Gm2. Specifically, the second bias current Ib2 provided by the second bias voltage source Vos2 in this embodiment and the second predetermined voltage V2 provided by the second bias current source Ios2 in the first embodiment may, for example, satisfy the following relationship: V2=Ib2/gm2.

### Embodiment 3

In particular applications, at least two parallel-connected second OTAs may be provided in the pull-up circuit, as required. The first and second input terminals of each second OTA are coupled to the first and second output terminals of the pre-amplifier, respectively. Moreover, a respective pull-up unit is connected between the output terminal of each second OTA and the output terminal of the first OTA. Additionally or alternatively, at least two parallel-connected third OTAs may be provided in the pull-down circuit, as required. The first and second input terminals of each third OTA are coupled to the first and second output terminals of the pre-amplifier Amp, respectively. Moreover, a respective pull-down unit is connected between the output terminal of each third OTA and the output terminal of the first OTA.

In one embodiment, a respective first bias voltage source may be coupled between the first input terminal of each second OTA and the first output terminal of the pre-amplifier. Alternatively, a respective first bias voltage source may be coupled between the second input terminal of each second OTA and the second output terminal of the pre-amplifier. Additionally, the multiple first bias voltage sources are configured to provide multiple first predetermined voltages V1. It is to be noted that these first predetermined voltages V1 may be equal or not. The multiple first bias voltage sources in the pull-up circuit may be configured to generate multiple different first predetermined voltages V1. In this way, depending on the difference (Vp−Vn) between the voltage Vp at the first output terminal of the pre-amplifier Amp and the voltage Vn at the second output terminal thereof, one(s) of the second OTAs may be activated. For example, more pull-up units may be activated in response to a greater value of the difference (Vp−Vn) between the voltage Vp at the first output terminal of the pre-amplifier Amp and the voltage Vn at the second output terminal. As a result, the output signal Vcomp can be even sooner pulled up to a desired value.

Likewise, a respective second bias voltage source may be coupled between the second input terminal of each third OTA and the second output terminal of the pre-amplifier Amp. Alternatively, a respective second bias voltage source may be coupled between the first input terminal of each third OTA and the first output terminal of the pre-amplifier Amp. Additionally, the multiple second bias voltage sources are configured to provide multiple second predetermined voltage V2. It is to be noted that these second predetermined voltages V2 may be equal or not. The multiple second bias voltage sources in the pull-down circuit may be configured to generate multiple different second predetermined voltage V2. In this way, depending on the difference (Vn−Vp) between the voltage Vn at the second output terminal of the pre-amplifier Amp and the voltage Vp at the first output terminal thereof, one(s) of the third OTAs may be activated. For example, more pull-down units may be activated in response to a greater value of the difference (Vp−Vn) between the voltage Vp at the first output terminal of the pre-amplifier Amp and the voltage Vn at the second output terminal. As a result, the output signal Vcomp can be even sooner pulled down to a desired value.

In another embodiment, a respective first bias current source may be coupled to the output terminal of each second OTA. Moreover, the first bias current sources are configured to provide multiple first bias currents. Each first bias current is equal to the product of a respective one of the first predetermined voltages V1 and a transconductance gain of a respective one of the second OTAs. Likewise, a respective second bias current source may be coupled to the output terminal of each third OTA. Moreover, the second bias current sources are configured to provide multiple second bias currents. Each second bias current is equal to the product of a respective one of the second predetermined voltages V2 and a transconductance gain of a respective one of the third OTAs. Similar to the above embodiment, in this embodiment, in response to a greater value of the difference (Vp−Vn) between the voltage Vp at the first output terminal of the pre-amplifier Amp and the voltage Vn at the second output terminal thereof, more pull-up units may be activated to allow the output signal Vcomp to be even sooner pulled up to a desired voltage. On the contrary, in response to a greater value of the difference (Vn−Vp) between the voltage Vn at the second output terminal of the pre-amplifier Amp and the voltage Vp at the first output terminal thereof, more pull-down units may be activated to allow the output signal Vcomp to be even sooner pulled down to a desired voltage.

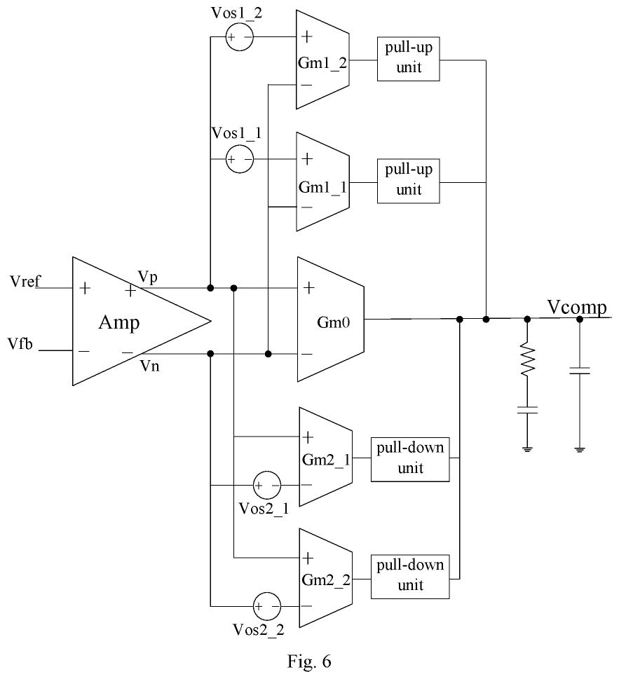

In an example of this embodiment, as shown in FIG. 6, there are two parallel-connected second OTAs Gm1_1, Gm1_2 in the pull-up circuit and two parallel-connected third OTAs Gm2_1, Gm2_2 in the pull-down circuit.

Specifically, in the pull-up circuit, first bias voltage sources Vos1_1, Vos1_2 are coupled to the first input terminals of the respective second OTAs Gm1_1, Gm1_2, and pull-up units are coupled to the output terminals of the respective second OTAs Gm1_1, Gm1_2. The first bias voltage sources Vos1_1, Vos1_2 may generate either equal or different voltages. When the difference (Vp−Vn) between the voltage Vp at the first output terminal of the pre-amplifier Amp and the voltage Vn at the second output terminal thereof is relatively large, either one or both of the pull-up units may be activated.

Moreover, in the pull-down circuit, second bias voltage sources Vos2_1, Vos2_2 are coupled to the second input terminals of the respective third OTAs Gm2_1, Gm2_2, and pull-down units are coupled to the output terminals of the respective third OTAs Gm2_1, Gm2_2. The second bias voltage sources Vos2_1, Vos2_2 may generate either equal or different equivalent voltages. When the difference (Vn−Vp) between the voltage Vn at the second output terminal of the pre-amplifier Amp and the voltage Vp at the first output terminal thereof is relatively large, either one or both of the pull-down units may be activated.

On the basis of the error amplifier as defined above, embodiments of the present invention also provide a power supply, which may be a switched-mode power supply (SMPS) or linear power supply. It is to be noted that, as an indispensable component of the power supply, the error amplifier is a core of a voltage-feedback control loop. The error amplifier can effect feedback of an output voltage and compensation of the entire control loop. Therefore, it plays a crucial role in the control of the entire loop and has a determinant impact on stability, load regulation and response of the power supply.

Specifically, for a power supply operating in a peak current mode, the error amplifier can be used to compare an output sample voltage (i.e., feedback voltage Vfb) corresponding to a load terminal of the power supply with a reference voltage Vref and thereby produce an amplified error signal Vcomp, which is then used to control a peak current through an inductor in the power supply. For a power supply operating in a voltage mode, an amplified error signal Vcomp produced by the error amplifier can be used to control an on-time (and hence duty cycle) of a power transistor in the power supply. In this way, the duty cycle of a control signal can be corrected, resulting in a stable output voltage. In the error amplifier as defined above, efficient load regulation can be achieved through a multi-branch pull-up or pull-down circuit, which provides a supplemental strategy through fast frequency response. This can stabilize the loop system and enables it to have desirable dynamic response.

It is to be understood that while the invention has been described above with reference to preferred embodiments thereof, it is not limited to these embodiments. In light of the above teachings, any person familiar with the art may make many possible modifications and variations to the disclosed embodiments or adapt them into equivalent embodiments, without departing from the scope of the invention. Accordingly, it is intended that any and all simple variations, equivalent changes and modifications made to the foregoing embodiments based on the substantive disclosure of the invention without departing from the scope thereof fall within this scope.

It is to be also noted that, as used herein, the terms “first”, “second”, “third” and the like are only meant to distinguish various components, elements, steps, etc. from each other rather than indicate logical or sequential orderings thereof, unless otherwise indicated or specified. As used herein, the term “plurality” means “two or more”. Further, it is also to be recognized that the terminology used herein is for the purpose of describing particular embodiments only, and is not intended to limit the scope of the present invention. It must be noted that, as used herein and in the appended claims, the singular forms “a” and “an” include the plural reference unless the context clearly dictates otherwise. Thus, for example, a reference to “a step” or “a means” is a reference to one or more steps or means and may include sub-steps and sub-means. All conjunctions used are to be understood in the most inclusive sense possible. Thus, the term “or” should be understood as having the definition of a logical “or” rather than that of a logical “exclusive or” unless the context clearly necessitates otherwise.

1. An error amplifier, comprising:
a steady-state circuit comprising a pre-amplifier and a first operational transconductance amplifier (OTA), a first input terminal of the pre-amplifier configured to receive a reference voltage, a second input terminal of the pre-amplifier configured to receive a feedback voltage, first and second input terminals of the first OTA coupled to first and second output terminals of the pre-amplifier, respectively, an output terminal of the first OTA connected to an output terminal of the error amplifier;
a pull-up circuit, a first input terminal of the pull-up circuit coupled to the first output terminal of the pre-amplifier, a second input terminal of the pull-up circuit coupled to the second output terminal of the pre-amplifier, the pull-up circuit configured to perform a pull-up operation when a difference between voltages at the first and second output terminals of the pre-amplifier is higher than a first predetermined voltage; and
a pull-down circuit, a first input terminal of the pull-down circuit coupled to the first output terminal of the pre-amplifier, a second input terminal of the pull-down circuit coupled to the second output terminal of the pre-amplifier, the pull-down circuit configured to perform a pull-down operation when a difference between the voltages at the second and first output terminals of the pre-amplifier is higher than a second predetermined voltage.

2. The error amplifier of claim 1, wherein the pull-up circuit comprises a second OTA and a pull-up unit connected between an output terminal of the second OTA and the output terminal of the first OTA, first and second input terminals of the second OTA coupled to the first and second output terminals of the pre-amplifier, respectively; and
the pull-down circuit comprises a third OTA and a pull-down unit coupled between an output terminal of the third OTA and the output terminal of the first OTA, first and second input terminals of the third OTA coupled to the first and second output terminals of the pre-amplifier, respectively.

3. The error amplifier of claim 2, wherein the pull-up circuit comprises a first bias voltage source for providing the first predetermined voltage, the first bias voltage source coupled between the first input terminal of the second OTA and the first output terminal of the pre-amplifier, or the first bias voltage source coupled between the second input terminal of the second OTA and the second output terminal of the pre-amplifier,
and/or wherein the pull-down circuit comprises a second bias voltage source for providing the second predetermined voltage, the second bias voltage source coupled between the second input terminal of the third OTA and the second output terminal of the pre-amplifier, or the second bias voltage source coupled between the first input terminal of the third OTA and the first output terminal of the pre-amplifier.

4. The error amplifier of claim 2, wherein the pull-up circuit comprises a first bias current source for providing a first bias current, the first bias current is configured according to the product of the first predetermined voltage and a transconductance gain of the second OTA, a first terminal of the first bias current source coupled to the output terminal of the second OTA, a second terminal of the first bias current source grounded,
and/or wherein the pull-down circuit comprises a second bias current source for providing a second bias current, the second bias current is configured according to the product of the second predetermined voltage and a transconductance gain of the third OTA, a first terminal of the second bias current source coupled to the output terminal of the third OTA, a second terminal of the second bias current source coupled to a power supply voltage.

5. The error amplifier of claim 2, wherein the pull-up unit comprises a first transistor, a second transistor, a third transistor and a fourth transistor,
a control terminal and a first terminal of the first transistor and a control terminal of the second transistor coupled to one another and then together to the output terminal of the first OTA, a second terminal of the first transistor and a second terminal of the second transistor coupled to each other and then both grounded, a first terminal of the second transistor coupled to a first terminal of the third transistor, a first terminal and a control terminal of the third transistor and a control terminal of the fourth transistor coupled to one another, a second terminal of the third transistor and a second terminal of the fourth transistor coupled to each other and then both to a power supply voltage, a first terminal of the fourth transistor connected to the output terminal of the first OTA.

6. The error amplifier of claim 2, wherein the pull-down unit comprises a fifth transistor, a sixth transistor, a seventh transistor and an eighth transistor,
a control terminal and a first terminal of the fifth transistor and a control terminal of the sixth transistor coupled to one another and then together to the output terminal of the third OTA, a second terminal of the fifth transistor and a second terminal of the sixth transistor coupled to each other and then both to a power supply voltage, a first terminal of the sixth transistor, a first terminal and a control terminal of the seventh transistor and a control terminal of the eighth transistor coupled to one another, a second terminal of the seventh transistor and a second terminal of the eighth transistor coupled to each other and then both grounded, a first terminal of the eighth transistor connected to the output terminal of the first OTA.

7. The error amplifier of claim 2, wherein the pull-up unit comprises a first switch coupled between the output terminal of the second OTA and the output terminal of the first OTA,
and/or wherein the pull-down unit comprises a second switch coupled between the output terminal of the third OTA and the output terminal of the first OTA.

8. The error amplifier of claim 1, wherein the pull-up circuit comprises at least two second OTAs, first and second input terminals of each second OTA coupled to the first and second output terminals of the pre-amplifier, respectively, a respective pull-up unit connected between an output terminal of each second OTA and the output terminal of the first OTA,
and/or wherein the pull-down circuit comprises at least two third OTAs, first and second input terminals of each third OTA coupled to the first and second output terminals of the pre-amplifier, respectively, a respective pull-down unit connected between an output terminal of each third OTA and the output terminal of the first OTA.

9. The error amplifier of claim 8, wherein a first bias voltage source is coupled between the first input terminal of each second OTA and the first output terminal of the pre-amplifier, or a first bias voltage source is coupled between the second input terminal of each second OTA and the second output terminal of the pre-amplifier,
and/or wherein a second bias voltage source is coupled between the second input terminal of each third OTA and the second output terminal of the pre-amplifier, or a second bias voltage source is coupled between the first input terminal of each third OTA and the first output terminal of the pre-amplifier.

10. The error amplifier of claim 8, wherein a first bias current source is coupled to an output terminal of each second OTA, and/or wherein a second bias current source is coupled to an output terminal of each third OTA.

11. The error amplifier of claim 8, wherein the pull-up unit comprises a first transistor, a second transistor, a third transistor and a fourth transistor,
a control terminal and a first terminal of the first transistor and a control terminal of the second transistor coupled to one another and then together to the output terminal of the first OTA, a second terminal of the first transistor and a second terminal of the second transistor coupled to each other and then both grounded, a first terminal of the second transistor coupled to a first terminal of the third transistor, a first terminal and a control terminal of the third transistor and a control terminal of the fourth transistor coupled to one another, a second terminal of the third transistor and a second terminal of the fourth transistor coupled to each other and then both to a power supply voltage, a first terminal of the fourth transistor connected to the output terminal of the first OTA.

12. The error amplifier of claim 8, wherein the pull-down unit comprises a fifth transistor, a sixth transistor, a seventh transistor and an eighth transistor,
a control terminal and a first terminal of the fifth transistor and a control terminal of the sixth transistor coupled to one another and then together to the output terminal of the third OTA, a second terminal of the fifth transistor and a second terminal of the sixth transistor coupled to each other and then both to a power supply voltage, a first terminal of the sixth transistor, a first terminal and a control terminal of the seventh transistor and a control terminal of the eighth transistor coupled to one another, a second terminal of the seventh transistor and a second terminal of the eighth transistor coupled to each other and then both grounded, a first terminal of the eighth transistor connected to the output terminal of the first OTA.

13. The error amplifier of claim 8, wherein the pull-up unit comprises a first switch coupled between the output terminal of the second OTA and the output terminal of the first OTA,
and/or wherein the pull-down unit comprises a second switch coupled between the output terminal of the third OTA and the output terminal of the first OTA.

14. A power supply, comprising the error amplifier of claim 1.

15. The power supply of claim 14, wherein the power supply is a current-mode power supply, in which the error amplifier generates an amplified error signal for controlling a peak value of a current through an inductor in the power supply, or wherein the power supply is a voltage-mode power supply, in which the error amplifier generates an amplified error signal for controlling a duty cycle of a power transistor in the power supply.
